(19) United States
(12) Patent Application Publication
(10) Pub. No.: US 2026/0371934 A1
(43) Pub. Date: Nov. 19, 2026

(54) PIEZOELECTRIC VIBRATOR

(71) Applicant: Murata Manufacturing Co., Ltd., Nagaokakyo-shi (JP)

(72) Inventor: Shigeo OJIMA, Nagaokakyo-shi (JP)

(21) Appl. No.: 19/734,621

(22) Filed: Jul. 8, 2026

Related U.S. Application Data
(63) Continuation of application No. PCT/JP2024/037790, filed on Oct. 23, 2024.

(30) Foreign Application Priority Data
Feb. 29, 2024 (JP) 2024-030414

(51) Int. Cl. H10N 30/88; H03B 5/32; H10N 30/87

(52) U.S. Cl. CPC H10N 30/883; H03B 5/32; H10N 30/872; H03B 2200/0018

(57) ABSTRACT

A piezoelectric vibrator that includes: a base member; a piezoelectric vibration element on the base member and including a piezoelectric piece and an excitation electrode configured to apply voltage to the piezoelectric piece; a lid member that defines an internal space together with the base member, the internal space accommodating the piezoelectric vibration element; and a bonding part bonding the base member and the lid member to seal the internal space. The bonding part includes an organic adhesive, and S/V/W≤6, wherein V is a volume of the internal space, W is a sealing width of the bonding part in the width direction, and S is a sealing sectional area representing a product of a sealing thickness t and a peripheral length Lc.

### CROSS REFERENCE TO RELATED APPLICATIONS

The present application is a continuation of International application No. PCT/JP2024/037790, filed Oct. 23, 2024, which claims priority to Japanese Patent Application No. 2024-030414, filed Feb. 29, 2024, the entire contents of each of which are incorporated herein by reference.

### TECHNICAL FIELD

The present disclosure relates to a piezoelectric vibrator.

### BACKGROUND ART

Piezoelectric vibration elements are used for timing devices, sensors, oscillators, and the like in various electronic devices such as mobile communication terminals, communication base stations, and home appliances. A piezoelectric vibration element includes a piezoelectric piece including a pair of main surfaces and a pair of excitation electrodes provided to the respective ones of the pair of main surfaces of the piezoelectric piece.

For example, Patent Document 1 discloses a piezoelectric oscillator part including a substrate, a piezoelectric oscillator held by the substrate, and a cap fixed to the substrate by an adhesive.

Patent Document 1: Japanese Patent No. 4,947,213

### SUMMARY OF THE DISCLOSURE

However, according to the piezoelectric oscillator part described in Patent Document 1, air and/or water vapor may enter through the adhesive, causing frequency fluctuation due to an increase in internal pressure or electrode oxidation.

The present disclosure has been made in view of such circumstances, and an object thereof is to provide a piezoelectric vibrator capable of suppressing frequency fluctuation.

A piezoelectric vibrator according to an aspect of the present disclosure includes: a base member; a piezoelectric vibration element mounted on the base member, the piezoelectric vibration element including a piezoelectric piece and an excitation electrode configured to apply voltage to the piezoelectric piece; a lid member that defines an internal space together with the base member, the internal space accommodating the piezoelectric vibration element; and a bonding part bonding the base member and the lid member to seal the internal space, wherein the bonding part includes an organic adhesive, and when a direction intersecting a peripheral direction of the bonding part along a main surface of the base member is a width direction, and a direction intersecting the main surface of the base member is a thickness direction, S/V/W≤6, wherein V is a volume of the internal space, W is a sealing width of the bonding part in the width direction, t is a sealing thickness of the bonding part in the thickness direction, Lc is a peripheral length of the bonding part in the peripheral direction, and S is a sealing sectional area representing a product of the sealing thickness t and the peripheral length Lc.

According to the present disclosure, a piezoelectric vibrator capable of achieving suppression of frequency fluctuation can be provided.

### BRIEF DESCRIPTION OF DRAWINGS

FIG. 1 is an exploded perspective view of a crystal vibrator according to a first embodiment.

FIG. 2 is a cross-sectional view of the crystal vibrator according to the first embodiment.

FIG. 3 is an enlarged cross-sectional view of a bonding part of the crystal vibrator according to the first embodiment.

FIG. 4 is a plan view of the crystal vibrator according to the first embodiment.

FIG. 5 is a graph showing frequency fluctuation according to examples based on the first embodiment.

FIG. 6 is a cross-sectional view of a crystal vibrator according to a second embodiment.

FIG. 7 is an enlarged cross-sectional view of a bonding part of the crystal vibrator according to the second embodiment.

FIG. 8 is a cross-sectional view of a crystal vibrator according to a third embodiment.

FIG. 9 is an enlarged cross-sectional view of a bonding part of the crystal vibrator according to the third embodiment.

FIG. 10 is a cross-sectional view of a crystal vibrator according to a fourth embodiment.

FIG. 11 is a graph showing fluctuation in equivalent series resistance according to examples based on the first embodiment.

### DESCRIPTION OF THE PREFERRED EMBODIMENTS

Embodiments of the present disclosure will be described below. In the following description with reference to the drawings, the same or similar components are denoted by the same or similar reference signs. The drawings are illustrative and dimensions and a shape of each part are schematic, and the technical scope of the present disclosure should not be interpreted as being limited to the embodiments.

In each drawing, an orthogonal coordinate system consisting of an X axis, a Y′ axis, and a Z′ axis may be provided for convenience in order to clarify a mutual relationship of the drawings and to help understanding of a positional relationship of members. The X axis, the Y′ axis, and the Z′ axis correspond between the drawings. The X axis, the Y′ axis, and the Z′ axis correspond to respective crystallographic axes of a crystal piece 11 described later. The X axis corresponds to an electrical axis (polar axis) of a crystal, a Y axis corresponds to a mechanical axis of the crystal, and a Z axis corresponds to an optical axis of the crystal. The Y′ axis and the Z′ axis are axes obtained by rotating the Y axis and the Z axis, respectively, counterclockwise about the X axis by θ degrees, when seen from a positive side in an X axis direction.

In the following description, a direction parallel to the X axis is referred to as the “X axis direction”, a direction parallel to the Y′ axis is referred to as a “Y′ axis direction”, and a direction parallel to the Z′ axis is referred to as a “Z′ axis direction”. Further, a direction of a tip of an arrow of each of the X axis, the Y′ axis, and the Z′ axis is referred to as “positive” or “+(plus)”, and a direction opposite to the arrow is referred to as “negative” or “−(minus)”. Note that, for convenience, description is provided assuming that the +Y′ axis direction is an upper direction and the −Y′ axis direction is a lower direction. However, the up-down direction of a crystal vibration element 10 and a crystal vibrator 1 is not limited. In addition, a plane defined by the X axis and the Z′ axis is referred to as a Z'-X plane, and the same applies to planes defined by other axes.

### First Embodiment

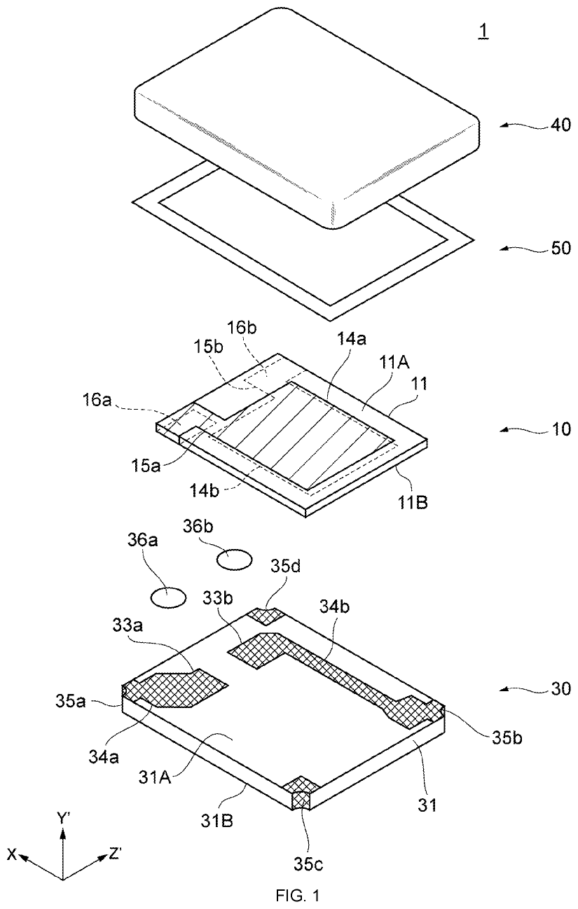

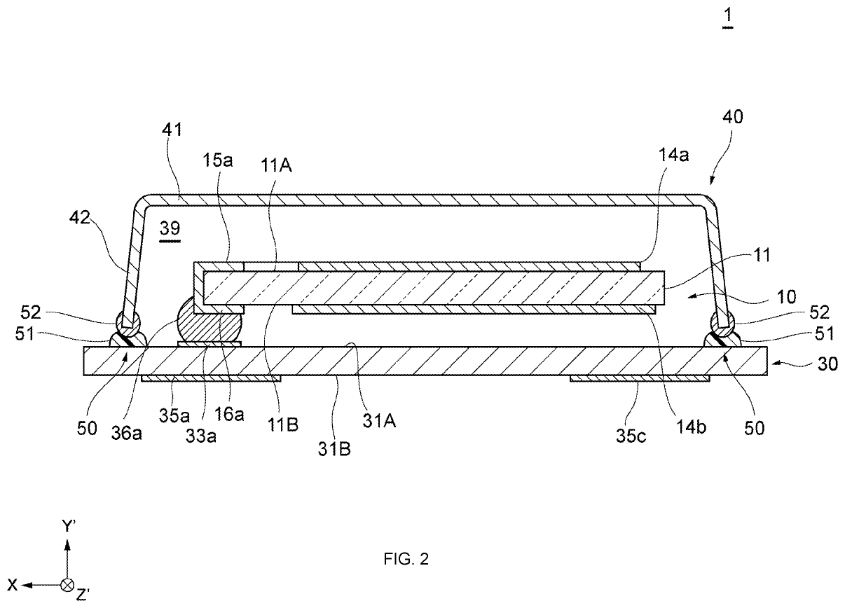

First, a configuration of a crystal vibrator according to a first embodiment will be described with reference to FIGS. 1 and 2. FIG. 1 is an exploded perspective view of the crystal vibrator according to the first embodiment. FIG. 2 is a cross-sectional view of the crystal vibrator according to the first embodiment.

The crystal vibrator 1 includes the crystal vibration element 10, a base member 30, a lid member 40, and a bonding part 50. Hereinafter, the Y′ axis direction is a “thickness direction” of the crystal vibration element 10.

For example, the crystal vibrator 1 is used as a component of a temperature compensated crystal oscillator (TCXO), a voltage controlled crystal oscillator (VCXO), or an oven controlled crystal oscillator (OCXO).

The crystal vibration element 10 is an electromechanical energy conversion element that converts between electrical energy and mechanical energy by a piezoelectric effect.

The crystal vibration element 10 is excited at a predetermined frequency based on an applied alternating voltage. The crystal vibration element 10 is held in a vibratable manner in a vibration space provided between the base member 30 and the lid member 40. Main vibration of the crystal vibration element 10 is a thickness shear vibration mode.

Note that the main vibration of the crystal vibration element is not limited to the thickness shear vibration mode, and may be, for example, a thickness expansion vibration mode, an area expansion vibration mode, a length vibration mode, or a flexural vibration mode.

As illustrated in FIG. 1, the crystal vibration element 10 includes a flake-shaped crystal piece (quartz crystal element) 11, a first excitation electrode 14a and a second excitation electrode 14b constituting a pair of excitation electrodes, a first extraction electrode 15a and a second extraction electrode 15b constituting a pair of extraction electrodes, and a first connection electrode 16a and a second connection electrode 16b constituting a pair of connection electrodes.

The crystal piece 11 includes an upper surface 11A and a lower surface 11B opposed to each other. The upper surface 11A is located on a side facing a ceiling part 41, which will be described later, of the lid member 40. The lower surface 11B is located on a side facing the base member 30. The upper surface 11A and the lower surface 11B correspond to a pair of main surfaces of the crystal piece 11.

The crystal piece 11 is, for example, an AT-cut quartz crystal. The AT-cut quartz crystal is formed such that its main surface is in the X-Z′ plane and a thickness direction is parallel to the Y′ axis. As an example, a shape of the crystal piece 11 (hereinafter referred to as a “planar shape”) when the upper surface 11A is seen in plan view in the thickness direction (hereinafter simply referred to as “plan view”) is an oblong shape. The oblong shape includes a pair of short sides extending in the Z′ axis direction and a pair of long sides extending in the X axis direction. As an example, the shape of the crystal piece 11 is a flat plate shape with a uniform thickness.

Note that the planar shape of the crystal piece is not limited to the above. For example, the planar shape of the crystal piece may be an oblong shape including long sides extending in the Z′ axis direction and short sides extending in the X axis direction, or a square shape including sides extending in the Z′ axis direction and sides extending in the X axis direction. The planar shape of the crystal piece may be a rectangular shape including sides extending in a direction intersecting the Z axis direction and the Z′ axis direction. The planar shape of the crystal piece may be a polygonal shape, a circular shape, an elliptical shape, or a combination thereof. Further, the crystal piece is not limited to having a flat plate shape. The crystal piece may have a mesa-type structure or an inverted-mesa-type structure in which at least one of the upper surface and the lower surface has unevenness. The crystal piece may have a convex structure in which an amount of change in thickness changes continuously, or a beveled structure in which an amount of change in thickness changes discontinuously.

The AT-cut crystal piece 11 is cut out in such a manner that axes obtained by rotating the Y axis and the Z axis among the X axis, the Y axis, and the Z axis in a direction from the Y axis to the Z axis about the X axis by 35 degrees 15 minutes ±1 minute 30 seconds are the Y′ axis and the Z′ axis, respectively, and a main surface is in the X-Z′ plane. The X axis, the Y axis, and the Z axis are crystal axes of a synthetic quartz crystal.

The crystal vibration element 10 using the AT-cut crystal piece 11 has high frequency stability over a wide temperature range. Further, the AT-cut crystal vibration element is also excellent in temporal-change characteristics and can be manufactured at low cost. In addition, the AT-cut crystal vibration element uses a thickness shear vibration mode as main vibration.

Note that the cut-angles of the crystal piece are not limited to the above. The rotation angle of the Y′ axis and the Z′ axis in the AT-cut crystal piece 11 may be tilted within a range of −5 degrees or more or +15 degrees or less from 35 degrees 15 minutes. Further, a cut other than the AT-cut, for example, BT-cut, GT-cut, SC-cut, or the like may be applied to the cut-angles of the crystal piece. In addition, the main vibration mode of the crystal vibration element is not limited to the thickness shear vibration mode, and may be, for example, a thickness expansion vibration mode, an area expansion vibration mode, a length vibration mode, or a flexural vibration mode.

The first excitation electrode 14a and the second excitation electrode 14b apply alternating voltage to the crystal piece 11 to excite the crystal piece 11. The first excitation electrode 14a and the second excitation electrode 14b are provided to a center portion of the crystal piece 11 in plan view. The first excitation electrode 14a is provided to the upper surface 11A, and the second excitation electrode 14b is provided to the lower surface 11B. The first excitation electrode 14a and the second excitation electrode 14b are opposed to each other in the Y′ axis direction with the crystal piece 11 interposed therebetween.

A planar shape of the first excitation electrode 14a is an oblong shape including short sides extending in the Z′ axis direction and long sides extending in the X axis direction. The first excitation electrode 14a has a thickness in the Y′ axis direction. The second excitation electrode 14b has a similar shape.

Note that the planar shape of each of the first excitation electrode and the second excitation electrode is not limited to the above. The planar shape of each of the first excitation electrode and the second excitation electrode may be an oblong shape including short sides extending in the X axis direction, or a square shape including sides extending in the X axis direction and sides extending in the Z′ axis direction. The planar shape of each of the first excitation electrode and the second excitation electrode may be a rectangular shape including sides extending in a direction intersecting the Z axis direction and the Z′ axis direction. The planar shape of each of the first excitation electrode and the second excitation electrode may be a polygonal shape, a circular shape, an elliptical shape, or a combination thereof.

The first extraction electrode 15a electrically connects the first excitation electrode 14a and the first connection electrode 16a, and the second extraction electrode 15b electrically connects the second excitation electrode 14b and the second connection electrode 16b. The first extraction electrode 15a is provided from the upper surface 11A to the lower surface 11B of the crystal piece 11, and the second extraction electrode 15b is provided to the lower surface 11B of the crystal piece 11.

The first connection electrode 16a and the second connection electrode 16b electrically connect the crystal vibration element 10 to the base member 30. The first connection electrode 16a and the second connection electrode 16b are provided to the lower surface 11B of the crystal piece 11.

The first excitation electrode 14a, the first extraction electrode 15a, and the first connection electrode 16a are provided integrally. The same applies to the second excitation electrode 14b, the second extraction electrode 15b, and the second connection electrode 16b. A group of electrodes consisting of the first excitation electrode 14a, the first extraction electrode 15a, and the first connection electrode 16a are first electrodes, and a group of electrodes consisting of the second excitation electrode 14b, the second extraction electrode 15b, and the second connection electrode 16b are second electrodes.

For example, each of the first electrode and the second electrode has a multilayer structure including an underlying layer and a surface layer stacked in this order. For example, the underlying layer is a chromium (Cr) layer with favorable adhesion to the crystal piece 11, and the surface layer is a gold (Au) layer with favorable chemical stability. The first electrode and the second electrode may include titanium (Ti), aluminum (Al), molybdenum (Mo), or an aluminum-copper alloy (AlCu) containing aluminum (Al) as a main component. Each of the first electrode and the second electrode may have a single-layer structure.

The base member 30 holds the crystal vibration element 10 in a vibratable manner. The base member 30 includes a base body 31, connection electrodes 33a and 33b, extraction electrodes 34a and 34b, and outer electrodes 35a, 35b, 35c, and 35d.

The base body 31 is a plate-shaped insulator including an upper surface 31A and a lower surface 31B opposed to each other in the thickness direction. The upper surface 31A and the lower surface 31B correspond to a pair of main surfaces of the base body 31. The upper surface 31A is located on a side facing the crystal vibration element 10 and the lid member 40 and corresponds to a mounting surface on which the crystal vibration element 10 is mounted. From a perspective of suppressing thermal stress acting on the crystal vibration element 10 from the base body 31 due to a thermal history such as reflow, the base body 31 is preferably made of a heat-resistant material. From the same perspective, the base body 31 may be made of a material having a coefficient of thermal expansion close to that of the crystal piece 11. The base body 31 is made of, for example, a ceramic substrate, a glass substrate, or a crystal substrate.

A corner portion of the base body 31 has a cut-out side surface partially formed in a shape with a cylindrical, curved surface (also called a castellation shape). Note that the shape of the corner portion of the base body 31 is not limited to this. The corner portion of the base body may have a cut-out side surface formed in a prismatic shape, or may be a substantially right-angled corner portion without a cutout.

The connection electrodes 33a and 33b are electrically connected to the crystal vibration element 10. The connection electrode 33a is electrically connected to the first connection electrode 16a of the crystal vibration element 10, and the connection electrode 33b is connected to the second connection electrode 16b of the crystal vibration element 10.

The extraction electrode 34a electrically connects the connection electrode 33a and the outer electrode 35a, and the extraction electrode 34b electrically connects the connection electrode 33b and the outer electrode 35b. The extraction electrodes 34a and 34b are provided to the upper surface 31A of the base body 31.

The outer electrodes 35a and 35b are outer terminals for electrically connecting the crystal vibration element 10 to an external substrate not illustrated. The outer electrode 35a electrically connects the first excitation electrode 14a of the crystal vibration element 10 to the external substrate, and the outer electrode 35b electrically connects the second excitation electrode 14b of the crystal vibration element 10 to the external substrate. One of the outer electrodes 35c and 35d is a ground electrode for grounding the lid member 40, and the other one of them is a dummy electrode not electrically connected to the crystal vibration element 10 and the lid member 40. Each of the outer electrodes 35a, 35b, 35c, and 35d is provided continuously from the respective one of cut-out side surfaces to the lower surface 31B. The cut-out side surfaces are provided to the corresponding ones of the four corner portions of the base body 31. In the example illustrated in FIG. 1, the outer electrode 35a and the outer electrode 35b are located diagonally at corners of the upper surface 31A of the base body 31, and the outer electrode 35c and the outer electrode 35d are located diagonally at the other corners of the upper surface 31A of the base body 31.

Note that the functions and positions of the outer electrodes 35a, 35b, 35c, and 35d are not limited to the above. Both of the outer electrodes 35c and 35d may be ground electrodes, or both of them may be dummy electrodes. The outer electrodes 35c and 35d may be omitted. The outer electrode 35c may be electrically connected to one of the outer electrodes 35a and 35b, and the outer electrode 35d may be electrically connected to the other one of the outer electrodes 35a and 35b. In plan view, the outer electrodes 35a and 35b may be located on the same short side of the upper surface 31A of the base body 31, or may be located on the same long side.

Conductive holding members 36a and 36b are provided to the base member 30 on the side closer to the crystal vibration element 10. The conductive holding members 36a and 36b electrically connect the base member 30 and the crystal vibration element 10 and also mechanically hold the crystal vibration element 10. The conductive holding member 36a electrically connects the first connection electrode 16a of the crystal vibration element 10 and the connection electrode 33a of the base member 30. The conductive holding member 36b electrically connects the second connection electrode 16b of the crystal vibration element 10 and the connection electrode 33b of the base member 30. The conductive holding members 36a and 36b are cured products of a conductive adhesive including a thermosetting resin, a photocurable resin, or the like. A main component of the conductive holding members 36a and 36b is, for example, a silicone resin. The conductive holding members 36a and 36b include conductive particles, and for example, metal particles including silver (Ag) are used as the conductive particles.

The main component of the conductive holding members 36a and 36b is not limited to a silicone resin, and may be, for example, an epoxy resin or an acrylic resin. The conductive particles included in the conductive holding members 36a and 36b are not limited to silver particles, and may be formed by another metal, a conductive ceramic, a conductive organic material, or the like. The conductive holding members 36a and 36b may include a conductive polymer.

The lid member 40 forms an internal space 39 accommodating the crystal vibration element 10 between the base member 30 and the lid member 40. The lid member 40 includes the ceiling part 41 and a side wall part 42 extending from an outer peripheral portion of the ceiling part 41 toward the base member 30. The ceiling part 41 is opposed to the base member 30 with the crystal vibration element 10 interposed between the base member 30 and the ceiling part 41 in the Y′ axis direction. The side wall part 42 surrounds the crystal vibration element 10 having a gap in the X-Z′ plane direction. A material for the lid member 40 is preferably a conductive material, and further preferably a highly airtight metal material. By the lid member 40 including a conductive material, an electromagnetic shielding function of reducing entrance and exit of electromagnetic waves into and from the internal space 39 may be imparted to the lid member 40. From a perspective of suppressing generation of thermal stress, the material for the lid member 40 is preferably a material having a coefficient of thermal expansion close to that of the base member 30, for example, an Fe-Ni-Co alloy whose coefficient of thermal expansion near room temperature matches that of glass or ceramics over a wide temperature range. The lid member 40 is electrically connected to at least one of the outer electrodes 35c and 35d by a grounding member not illustrated.

Note that the material for the lid member is not limited to a conductive material. The material for the lid member may be an insulating material such as ceramic. Accordingly, an electrode crossing the bonding part provided to the main surface of the base member is not electrically short-circuited via the lid member, and thus the bonding part can have a reduced thickness. When the lid member is made of ceramic, the base body of the base member and the lid member are preferably made of the same material from a perspective of suppressing generation of thermal stress.

The bonding part 50 bonds the base member 30 and the lid member 40 to seal the internal space 39. The bonding part 50 is provided in a frame shape surrounding the crystal vibration element 10 along an end portion (hereinafter referred to as a “tip portion”) of the side wall part 42 of the lid member 40 on a side closer to the base member 30. The bonding part 50 is sandwiched between the tip portion of the side wall part 42 of the lid member 40 and the upper surface 31A of the base member 30.

The bonding part 50 includes an insulating film 52 and an organic adhesive 51.

The insulating film 52 covers the tip portion of the side wall part 42 of the lid member 40. The organic adhesive 51 bonds the insulating film 52 and the base member 30. The insulating film 52 is made of, for example, an organic insulating material including an epoxy-based, vinyl-based, acrylic-based, urethane-based, or silicone-based resin. The organic adhesive 51 is, for example, an adhesive including an epoxy-based, vinyl-based, acrylic-based, urethane-based, or silicone-based resin. The insulating film 52 increases a contact area with respect to the bonding part 50, which improves bonding strength. Further, the insulating film 52 reduces variation in thickness of the organic adhesive 51 caused by positional variation of the tip portion of the side wall part 42 due to waviness of the lid member 40. That is, a tip portion of the insulating film 52 has greater flatness than that of the tip portion of the side wall part 42, and thereby a decrease in bonding strength or a decrease in sealability due to variation in thickness of the organic adhesive 51 is suppressed.

An elastic modulus of the organic adhesive 51 is, for example, 3 GPa to 7 GPa. The organic adhesive 51 may include, for example, an insulating filler. The insulating filler is sandwiched between the base member 30 and the lid member 40 and functions as a spacer securing a gap of a certain amount or more between the base member 30 and the lid member 40. A material for the insulating filler is not particularly limited as long as it is an insulating material, and examples thereof include resin, limestone, and clay. The insulating filler made of resin is, for example, spherical particles each having a particle size of 3 μm to 100 μm.

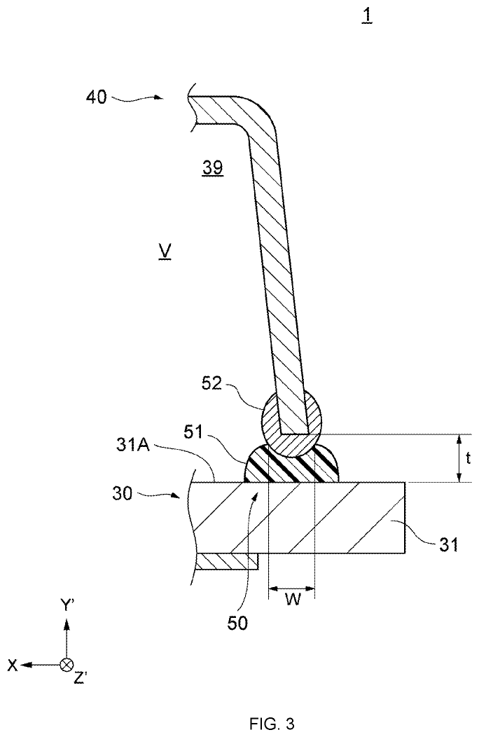

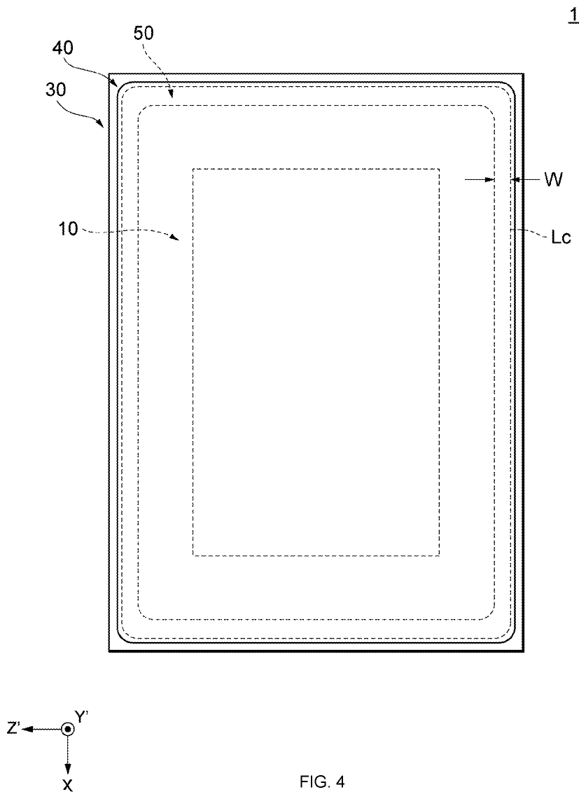

Next, dimensions of the bonding part 50 according to the first embodiment will be described with reference to FIGS. 3 and 4. FIG. 3 is an enlarged cross-sectional view of the bonding part of the crystal vibrator according to the first embodiment. FIG. 4 is a plan view of the crystal vibrator according to the first embodiment.

Regarding the bonding part 50, a direction intersecting a peripheral direction of the bonding part 50 along the upper surface 31A of the base body 31 of the base member 30 is a width direction, and a direction intersecting the upper surface 31A of the base body 31 of the base member 30 is a thickness direction. Note that the upper surface 31A of the base body 31 corresponds to an example of the main surface of the base member 30.

A volume of the internal space 39 of the crystal vibrator 1 is an internal volume V. The internal volume V is a volume of a space surrounded by the base body 31 of the base member 30 and the lid member 40 and is a volume including volumes of the crystal vibration element 10, the conductive holding members 36a and 36b, and the like. In order to reduce influence of gas that has entered the internal space 39 on the crystal vibration element 10, the internal volume V is preferably large.

A dimension of the bonding part 50 in the width direction is a sealing width W. The sealing width W is a distance in the width direction between an inner side surface of the bonding part 50 closer to the internal space 39 and an outer side surface of the bonding part 50 opposite to the internal space 39. The sealing width W is identified as, for example, an average value of sealing widths in respective ones of a plurality of cross sections of the bonding part 50, but may be identified as a sealing width in a cross section at a specific position. The sealing width of the bonding part 50 in a certain cross section is identified as, for example, a minimum value or an average value of the dimension of the bonding part 50 in the width direction. The sealing width of the bonding part 50 in a certain cross section may be identified as a dimension of a portion of the base member 30 in the width direction. The portion is in contact with the bonding part 50. The sealing width of the bonding part 50 in a certain cross section may be identified as a dimension of a portion of the lid member 40 in the width direction. The portion is in contact with the bonding part 50. In this case, for example, the sealing width W is identified as a thickness of the lid member 40. In order to make entry of gas from the outside into the internal space 39 through the bonding part 50 (hereinafter referred to as “gas barrier property of the bonding part 50”) more difficult, the sealing width W is preferably large.

A dimension of the bonding part 50 in the thickness direction is a sealing thickness t. The sealing thickness t is a distance in the thickness direction between a bonded surface of the base member 30 in contact with the bonding part 50 and a bonded surface of the lid member 40 in contact with the bonding part 50. The sealing thickness t is identified as, for example, an average value of sealing thicknesses in respective ones of a plurality of cross sections of the bonding part 50, but may be identified as a sealing thickness in a cross section at a specific position. The sealing thickness of the bonding part 50 in a certain cross section is identified as, for example, a maximum value or an average value of a dimension of a portion of the bonding part 50 in the thickness direction. The portion is sandwiched between the base member 30 and the lid member 40. In order to improve the gas barrier property of the bonding part 50, the sealing thickness t is preferably small. In order to reduce the sealing thickness t, flatness of the bonded surface of the base member 30 in contact with the bonding part 50 is preferably no greater than 3 μm, and flatness of the bonded surface of the tip portion of the side wall part 42 of the lid member 40 is preferably no greater than 3 μm. The bonded surface of the tip portion of the side wall part 42 of the lid member 40 is opposed to the base member 30 and in contact with the bonding part 50.

A dimension of the bonding part 50 in the peripheral direction is a peripheral length Lc. The peripheral length Lc is a length of an outermost periphery of an outer side surface of the bonding part 50 in plan view. The peripheral length Lc is identified as, for example, a length of an outermost periphery of the lid member 40 in plan view. A product of the sealing thickness t and the peripheral length Lc is a sealing sectional area S (S=t×Lc). In order to improve the gas barrier property of the bonding part 50, the peripheral length Lc is preferably small and the sealing sectional area S is preferably small.

Summarizing the internal volume V, the sealing width W, and the sealing sectional area S, in order to improve the gas barrier property of the bonding part 50 and reduce influence of gas that has entered the internal space 39, a parameter S/V/W is preferably small. For example, in the crystal vibrator 1, a relationship of S/V/W≤6 is satisfied, and preferably a relationship of S/V/W≤4 is satisfied. Further, from a perspective of processing accuracy, a relationship of 1.5≤S/V/W is preferably satisfied. Note that “S/V/W” is a parameter obtained by dividing S by V and further dividing the result by W, and can also be expressed as S/(V×W).

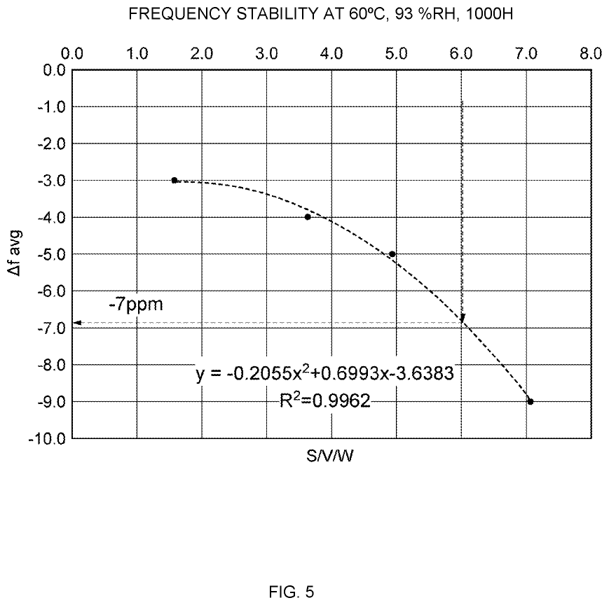

Next, a relationship between S/V/W and frequency fluctuation will be described with reference to FIG. 5. FIG. 5 is a graph showing frequency fluctuation in examples based on the first embodiment and a comparative example. In the graph illustrated in FIG. 5, a horizontal axis indicates S/V/W. In the graph illustrated in FIG. 5, a vertical axis indicates an average value Δfavg of frequency fluctuation in a damp heat durability test of a plurality of crystal vibration elements in each example based on the first embodiment and the comparative example. Conditions of the durability test include a test temperature of 60 °C, a test humidity of 93% RH, and a test time of 1000 hours. Frequency fluctuation Δf is a difference in frequency before and after the durability test. Note that, under a damp heat environment, gas that has entered the internal space 39 of the crystal vibrator 1 increases internal pressure of the crystal vibrator 1 and acts as resistance to vibration of the crystal vibration element 10, thereby reducing the frequency. Further, under the damp heat environment, water vapor and oxygen that have entered the internal space 39 of the crystal vibrator 1 oxidize an electrode of the crystal vibration element 10 and increase the mass of the crystal vibration element 10, thereby reducing the frequency.

### Comparative Example

Dimensions of base body 31 of base member 30 in plan view: 1.65 mm×1.25 mm

Material for base body 31 of base member 30: Alumina

Dimensions of lid member 40 in plan view: 1.53 mm×1.13 mm

Material for lid member 40: Fe—Ni—Co alloy

Material for organic adhesive 51: Epoxy-based resin

Elastic modulus of organic adhesive 51: 3 GPa

Internal volume V of internal space 39: 0.17 mm³

Sealing sectional area S of bonding part 50: 0.12 mm²

Sealing width W of bonding part 50: 0.10 mm

S/V/W=7.1

Δfavg=−9.0 ppm

### First Example

Dimensions of base body 31 of base member 30 in plan view: 1.65 mm×1.25 mm

Material for base body 31 of base member 30: Alumina

Dimensions of lid member 40 in plan view: 1.53 mm×1.13 mm

Material for lid member 40: Fe—Ni—Co alloy

Material for organic adhesive 51: Epoxy-based resin

Elastic modulus of organic adhesive 51: 3 GPa to 7 GPa

Internal volume V of internal space 39: 0.21 mm³

Sealing sectional area S of bonding part 50: 0.07 mm²

Sealing width W of bonding part 50: 0.07 mm

S/V/W=4.8

Δfavg=−5.0 ppm

In the organic adhesive 51 of the first embodiment, resin spherical particles each having a particle size of 10 μm are added, and the insulating film 52 is assumed to be omitted.

### Second Example

Dimensions of base body 31 of base member 30 in plan view: 1.25 mm×1.05 mm

Material for base body 31 of base member 30: Alumina

Dimensions of lid member 40 in plan view: 1.24 mm×1.04 mm

Material for lid member 40: Ceramic

Material for organic adhesive 51: Epoxy-based resin

Elastic modulus of organic adhesive 51: 7 GPa

Internal volume V of internal space 39: 0.45 mm³

Sealing sectional area S of bonding part 50: 0.18 mm²

Sealing width W of bonding part 50: 0.11 mm

S/V/W=3.6

Δfavg =−4.0 ppm

### Third Example

Dimensions of base body 31 of base member 30 in plan view: 2.05 mm×1.65 mm

Material for base body 31 of base member 30: Alumina

Dimensions of lid member 40 in plan view: 1.82 mm×1.62 mm

Material for lid member 40: Fe—Ni—Co alloy

Material for organic adhesive 51: Epoxy-based resin

Elastic modulus of organic adhesive 51: 7 GPa

Internal volume V of internal space 39: 0.2 mm³

Sealing sectional area S of bonding part 50: 0.04 mm²

Sealing width W of bonding part 50: 0.14 mm

S/V/W=1.4

Δfavg =−3.0 ppm

In the third embodiment, electrical connections between the connection electrodes 33a and 33b of the base member 30 and the outer electrodes 35a and 35b, respectively, are realized by corresponding through electrodes penetrating the base body 31 in the thickness direction, and it is assumed that an extraction electrode overlapping the bonding part 50 is not formed. Thereby, the bonded surface of the base member 30 has improved flatness. The bonded surface is bonded via the bonding part 50. Such an improvement in flatness of the bonded surface leads to a reduction in the sealing thickness t, which is an average value of the thickness of the bonding part 50, and a reduction in the sealing sectional area S, which is proportional to the sealing thickness t.

The inventors have found that there is a correlation as shown in FIG. 5 between the parameter S/V/W and the average value Δfavg of the frequency fluctuation. As S/V/W reduces, Δfavg approaches 0, and as S/V/W increases, Δfavg reduces. Here, “Δfavg reduces” means that an absolute value of Δfavg that is a negative value becomes larger. As S/V/W increases, an amount of change in Δfavg relative to an amount of change in S/V/W increases. The lower the gas barrier property of the bonding part 50 is, the smaller Δfavg is. Δfavg being small means that the frequency fluctuation under the damp heat environment is large. Based on the graph illustrated in FIG. 5, it can be seen that as S/V/W reduces, the frequency fluctuation under the damp heat environment reduces, and thus the damp heat durability is higher. For example, by a relationship of S/V/W≤6.0 being satisfied, −7.0 ppm≤Δfavg can be realized. That is, the frequency fluctuation after 1000 hours of elapsed time at 60 °C and 93% RH can be suppressed to be equal to or less than 7.0 ppm. Further, by a relationship of S/V/W≤4.0 being satisfied, −4.1 ppm≤Δfavg can be realized. That is, the frequency fluctuation after 1000 hours of elapsed time at 60 °C and 93% RH can be suppressed to be equal to or less than 4.1 ppm.

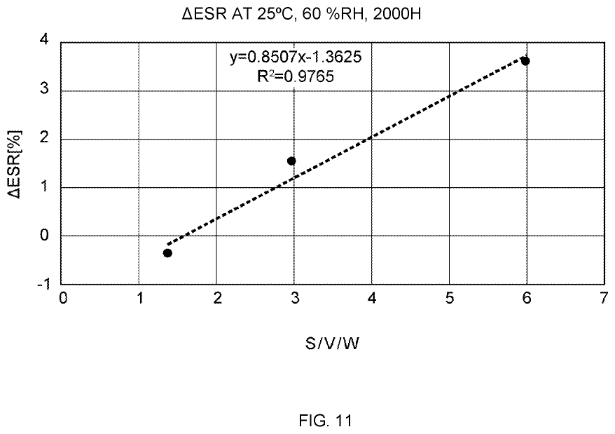

Next, a relationship between S/V/W and equivalent series resistance (ESR) will be described with reference to FIG. 11. FIG. 11 is a graph showing fluctuation in the equivalent series resistance based on the first embodiment. In the graph illustrated in FIG. 11, a horizontal axis indicates S/V/W, and a vertical axis indicates a fluctuation rate ΔESR [%] of the equivalent series resistance in a moisture resistance test. Conditions of the moisture resistance test include a test temperature of 25 °C, a test humidity of 60% RH, and a test time of 2000 hours. ΔESR is calculated by the following equation: ΔESR={(ESR_2000−ESR_0)/ESR_0}×100, where ESR_0 is equivalent series resistance before the test and ESR_2000 is equivalent series resistance after the test. That is, ΔESR being a positive value means that ESR is increased through the moisture resistance test. When moisture resistance of the crystal vibrator 1 is low, water vapor and oxygen that have entered the internal space 39 of the crystal vibrator 1 oxidize an electrode of the crystal vibration element 10, which increases ΔESR. Smaller ESR is more advantageous for oscillation, and thereby ΔESR is preferably small.

The inventors have found that there is a correlation as illustrated in FIG. 11 between the parameter S/V/W and the fluctuation rate ΔESR of the equivalent series resistance. As illustrated in FIG. 11, ΔESR is approximately 3.7% when S/V/W is approximately 6.0, ΔESR is approximately 1.6% when S/V/W is approximately 2.9, and ΔESR is approximately −0.3% when S/V/W is approximately 1.3. Based on these data, it is found that ΔESR shows a linear correlation with S/V/W; for example, ΔESR is approximately 0 when S/V/W is approximately 1.5. As S/V/W reduces, ΔESR reduces. ΔESR being small means that the crystal vibrator 1 has high moisture resistance, thus indicating that the moisture resistance of the crystal vibrator 1 increases as S/V/W reduces. For example, by the relationship of S/V/W≤6.0 being satisfied, ΔESR can be equal to or less than 4%, by a relationship of S/V/W≤5.0 being satisfied, ΔESR can be equal to or less than 3%, by the relationship of S/V/W ≤4.0 being satisfied, ΔESR can be equal to or less than 2%, and by a relationship of S/V/W≤2.4 being satisfied, ΔESR can be equal to or less than 1%.

As described above, according to this embodiment, the crystal vibrator 1 includes the crystal vibration element 10, the base member 30 on which the crystal vibration element 10 is mounted, the lid member 40 forming the internal space 39 accommodating the crystal vibration element 10 between the base member 30 and the lid member 40, and the bonding part 50 bonding the base member 30 and the lid member 40 to seal the internal space 39. The bonding part 50 includes the organic adhesive 51. The internal volume V of the internal space 39, the sealing width W of the bonding part 50, and the sealing sectional area S of the bonding part 50 satisfy the relationship of S/V/W≤6.

Accordingly, frequency fluctuation of the crystal vibrator 1 caused by gas that has entered the internal space 39 through the bonding part 50 can be suppressed; for example, the frequency fluctuation can be equal to or less than 7.0 ppm.

As a mode of this embodiment, the relationship of S/V/W≤4 is satisfied.

Accordingly, the frequency fluctuation of the crystal vibrator 1 can be further suppressed; for example, the frequency fluctuation can be equal to or less than 4.1 ppm.

As a mode of this embodiment, the relationship of 1.5 ≤S/V/W is satisfied.

Accordingly, an increase in manufacturing difficulty of the crystal vibrator 1 due to requirement for fine processing can be suppressed, and a decrease in yield of the crystal vibrator 1 can be suppressed.

As a mode of this embodiment, the elastic modulus of the organic adhesive 51 is 3 GPa to 7 GPa.

Accordingly, by the organic adhesive 51 having the elastic modulus of equal to or more than 3 GPa, the organic adhesive 51 can have an improved gas barrier property. By the organic adhesive 51 having the elastic modulus of equal to or less than 7 GPa, handleability can be improved, and occurrence of a defective product, such as occurrence of peeling of the bonding part 50, can be suppressed.

As a mode of this embodiment, the organic adhesive 51 includes the insulating filler, and the insulating filler is sandwiched between the base member 30 and the lid member 40.

Accordingly, the insulating filler ensures a gap between the base member 30 and the lid member 40, and thereby short-circuiting of an electrode on the base member 30 via the lid member 40 is suppressed. Therefore, when the lid member 40 is bonded to the base member 30, the lid member 40 can be brought close to the base member 30 without concern about short-circuiting, which can reduce the sealing thickness t.

Note that in this embodiment the base member 30 has a flat shape on the side closer to the crystal vibration element 10 and the lid member 40 has a recessed shape on the side closer to the crystal vibration element 10. However, the embodiment according to the present disclosure is not limited thereto. For example, the base member may have a recessed shape on the side closer to the crystal vibration element and the lid member may have a flat shape on the side closer to the crystal vibration element. Alternatively, both the base member and the lid member may have a recessed shape on the side closer to the crystal vibration element.

Below, other embodiments will be described. Note that configurations the same as or similar to those described in the first embodiment are denoted by the same or similar reference signs, and description thereof is omitted as appropriate. Further, similar operation and effects attributed to similar configurations will not be described one by one.

### Second Embodiment

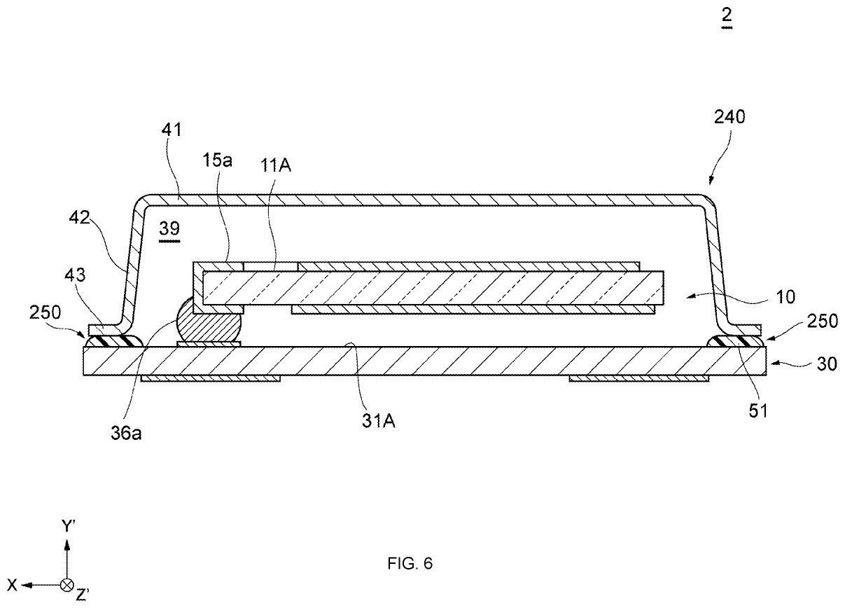

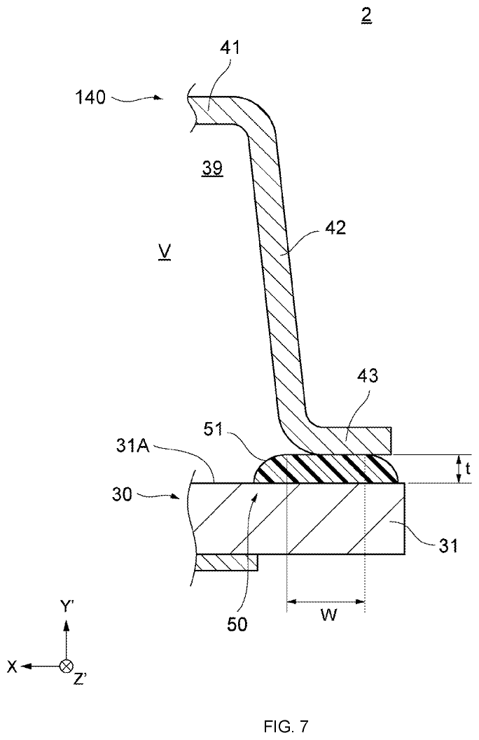

Next, a configuration of a crystal vibrator 2 according to a second embodiment will be described with reference to FIGS. 6 and 7. FIG. 6 is a cross-sectional view of the crystal vibrator according to the second embodiment. FIG. 7 is an enlarged cross-sectional view of a bonding part of the crystal vibrator according to the second embodiment.

A lid member 240 of the crystal vibrator 2 further includes a flange part 43. The flange part 43 extends from the tip portion of the side wall part 42 on the side closer to the base member 30 to a side opposite to the internal space 39. The flange part 43 is provided in a frame shape in plan view and is provided to the lid member 240 at a position closest to the base member 30. A bonding part 250 is sandwiched between the flange part 43 and the base member 30. A width of the flange part 43 is larger than a width of the tip portion of the side wall part 42, and thus the sealing width W can be increased. Further, with the flange part 43, a contact area between the lid member 240 and the bonding part 250 can be increased, which improves adhesion between the lid member 240 and the bonding part 250. Therefore, as illustrated in FIGS. 6 and 7, the insulating film 52 may be omitted in the bonding part 250.

### Third Embodiment

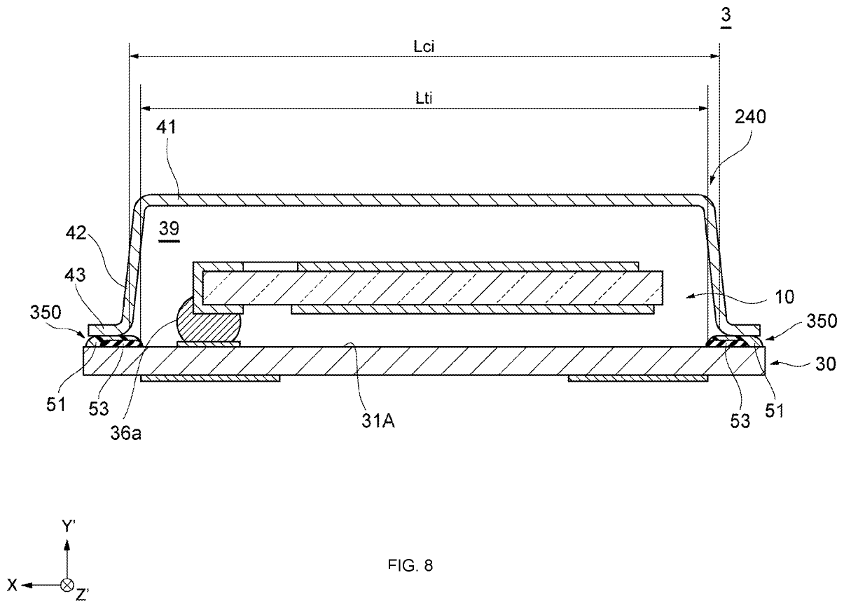

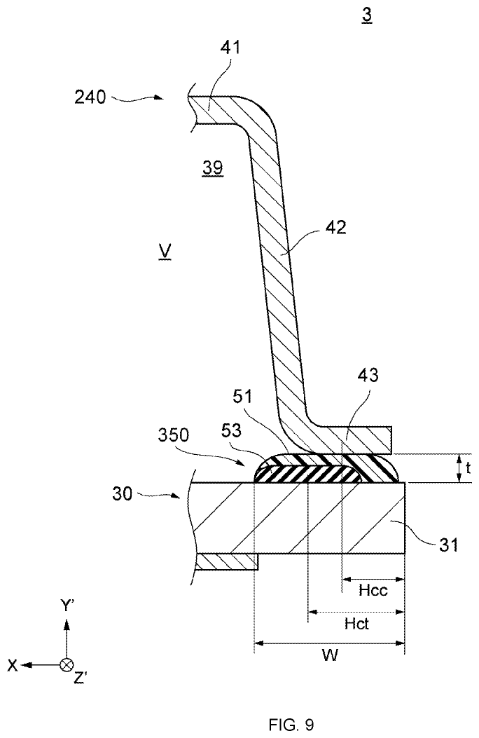

Next, a configuration of a crystal vibrator 3 according to a third embodiment will be described with reference to FIGS. 8 and 9. FIG. 8 is a cross-sectional view of the crystal vibrator according to the third embodiment. FIG. 9 is an enlarged cross-sectional view of a bonding part of the crystal vibrator according to the third embodiment.

A bonding part 350 of the crystal vibrator 3 includes the organic adhesive 51 and a projection part 53. The projection part 53 is provided to a surface of the base member 30. The surface is to be bonded to the lid member 240. The projection part 53 is made of, for example, an organic insulating material including an epoxy-based, vinyl-based, acrylic-based, urethane-based, or silicone-based resin. Accordingly, the projection part 53 functions as an insulating spacer. Therefore, even when the lid member 240 is brought close to the base member 30 to reduce the sealing thickness t, short-circuiting of an electrode provided to the surface of the base member 30 via the lid member 240 can be suppressed.

Flatness of a surface of the projection part 53 on a side closer to the lid member 240 is greater than flatness of the upper surface 31A of the base body 31 of the base member 30. Accordingly, variation in thickness of the organic adhesive 51 in a peripheral direction of the bonding part 350 can be suppressed. For example, in a closest region where a gap between the flange part 43 and the base member 30 is smallest, approach of the flange part 43 to the base member 30 is restricted, and thus an increase in the gap between the flange part 43 and the base member 30 in regions other than the closest region can be suppressed. Therefore, an increase in the sealing thickness t, which is an average value of a thickness of the bonding part 350, can be suppressed.

An inner end portion of the projection part 53 closer to the crystal vibration element 10 in the width direction is provided closer to the crystal vibration element 10 than an inner end portion of the flange part 43 closer to the crystal vibration element 10 in the width direction. Further, a center portion of the projection part 53 in the width direction is provided closer to the internal space 39 than a center portion of the bonding part 350 in the width direction, and is provided closer to the internal space 39 than a center portion of the flange part 43 in the width direction. As illustrated in FIG. 8, a distance Lti between the inner end portions of the projection part 53 closer to the crystal vibration element 10 in the width direction is smaller than a distance Lci between the inner end portions of the flange part 43 closer to the crystal vibration element 10 in the width direction. As illustrated in FIG. 9, in a cross section taken in the width direction, a distance Hct in the width direction from an outermost end of the crystal vibrator 1 to the center of the projection part 53 is larger than a distance Hcc in the width direction from the outermost end of the crystal vibrator 1 to the center of the flange part 43. Accordingly, wet spreading of the organic adhesive 51 toward the internal space 39 can be restricted by the projection part 53, and a surface area of the organic adhesive 51 on the side closer to the internal space 39 can be reduced. Therefore, frequency fluctuation caused by attachment of an organic substance derived from the organic adhesive 51, to the crystal vibration element 10 can be suppressed.

Note that in this embodiment the projection part is provided to the base member, but this is not limitative. The projection part may be provided to the lid member, or may be provided to both the base member and the lid member.

### Fourth Embodiment

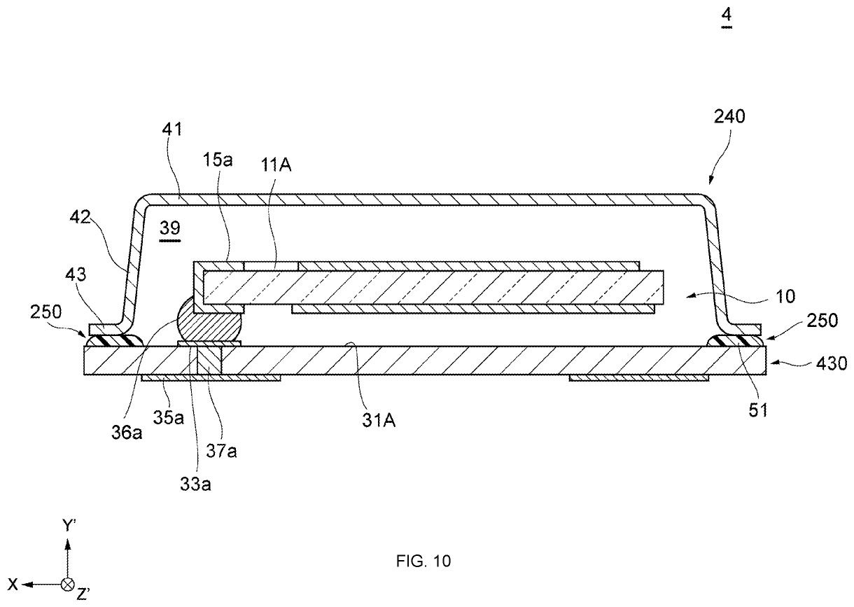

Next, a configuration of a crystal vibrator 4 according to a fourth embodiment will be described with reference to FIG. 10. FIG. 10 is a cross-sectional view of the crystal vibrator according to the fourth embodiment.

A base member 430 of the crystal vibrator 4 is provided with a through electrode 37a electrically connecting the connection electrode 33a and the outer electrode 35a. The through electrode 37a penetrates the base body 31 in the thickness direction. In the base member 430, instead of including the through electrode 37a, the extraction electrode 34a is omitted. Although not illustrated, the base member 430 is similarly provided with a through electrode 37b electrically connecting the connection electrode 33b and the outer electrode 35b. Accordingly, an extraction electrode crossing the bonding part 250 can be omitted, which can improve flatness of a bonded surface of the base member 430.

Note that herein the crystal vibration element (quartz crystal resonator) including the crystal piece (quartz crystal element) as the piezoelectric piece (piezoelectric element) has been described as an example, but the piezoelectric vibration element (piezoelectric resonator) is not limited thereto. Examples of the piezoelectric piece that is suitably used for the piezoelectric vibrator according to this embodiment include piezoelectric ceramics such as PZT and aluminum nitride, and piezoelectric single crystals such as lithium niobate and lithium tantalate, but are not limited thereto and can be selected as appropriate.

The embodiments according to the present disclosure can be appropriately applied without particular limitation as long as the embodiments are applied to a device that performs electromechanical energy conversion by a piezoelectric effect, such as a timing device, a sound producing device, an oscillator, or a load sensor.

As described above, according to a mode of the present disclosure, a piezoelectric vibrator capable of achieving suppression of frequency fluctuation can be provided.

Note that the embodiments described above are for facilitating understanding of the present disclosure, and not for limiting interpretation of the present disclosure. The present disclosure may be changed/modified without departing from the spirit of the present disclosure and includes equivalents thereof. That is, the scope of the present disclosure includes designs obtained by appropriately changing the embodiments and/or modifications by those skilled in the art as long as the designs include the features of the present disclosure. For example, each component included in the embodiments and/or modifications, and the arrangement, material, condition, shape, size, and the like of the component are not limited to those illustrated, and can be changed as appropriate. In addition, the embodiments and modifications are illustrative, and it is understood that the configurations described in different embodiments and/or modifications can be partially substituted or combined, and the substitutions or combinations are also included within the scope of the present disclosure as long as they include the features of the present disclosure.

### REFERENCE SIGNS LIST

1 crystal vibrator
10 crystal vibration element
30 base member
31 base body
31A upper surface
31B lower surface
39 internal space
40 lid member
41 ceiling part
42 side wall part
43 flange part
50 bonding part
51 organic adhesive
52 insulating film
11 crystal piece
11A upper surface
11B lower surface
14a first excitation electrode
14b second excitation electrode
15a first extraction electrode
15b second extraction electrode
16a first connection electrode
16b second connection electrode
V internal volume
W sealing width
t sealing thickness
Lc peripheral length
S sealing sectional area

1. A piezoelectric vibrator comprising:
a base member;
a piezoelectric vibration element mounted on the base member, the piezoelectric vibration element including a piezoelectric piece and an excitation electrode configured to apply voltage to the piezoelectric piece;
a lid member that defines an internal space together with the base member, the internal space accommodating the piezoelectric vibration element; and
a bonding part bonding the base member and the lid member to seal the internal space, wherein
the bonding part includes an organic adhesive, and
when a direction intersecting a peripheral direction of the bonding part along a main surface of the base member is a width direction, and a direction intersecting the main surface of the base member is a thickness direction, S/V/W≤6, wherein V is a volume of the internal space, W is a sealing width of the bonding part in the width direction, t is a sealing thickness of the bonding part in the thickness direction, Lc is a peripheral length of the bonding part in the peripheral direction, and S is a sealing sectional area representing a product of the sealing thickness t and the peripheral length Lc.

2. The piezoelectric vibrator according to claim 1, wherein S/V/W≤4.

3. The piezoelectric vibrator according to claim 1, wherein 1.5≤S/V/W.

4. The piezoelectric vibrator according to claim 1, wherein S/V/W≤2.4.

5. The piezoelectric vibrator according to claim 1, wherein an elastic modulus of the organic adhesive is 3 GPa to 7 GPa.

6. The piezoelectric vibrator according to claim 1, wherein the organic adhesive comprises an epoxy-based resin.

7. The piezoelectric vibrator according to claim 1, wherein
the organic adhesive includes an insulating filler, and
the insulating filler is sandwiched between the base member and the lid member.

8. The piezoelectric vibrator according to claim 1, wherein
the base member includes a bonded surface bonded to the lid member and the lid member includes a bonded surface bonded to the base member, and
at least one of the bonded surface of the base member and the bonded surface of the lid member includes a projection part.

9. The piezoelectric vibrator according to claim 8, wherein a center portion of the projection part in the width direction is closer to the internal space than a center portion of the bonding part in the width direction.

10. The piezoelectric vibrator according to claim 8, wherein the projection part comprises an insulating material.

11. The piezoelectric vibrator according to claim 10, wherein the insulating material of the projection part comprises an epoxy-based resin, a vinyl-based resin, an acrylic-based resin, a urethane-based resin, or a silicone-based resin.

12. The piezoelectric vibrator according to claim 8, wherein a flatness of a surface of the projection part on a side closer to the lid member is greater than a flatness of a surface of the base member.

13. The piezoelectric vibrator according to claim 1, wherein at least one of the lid member and the base member has a recessed shape on a side thereof closer to the piezoelectric vibration element.

14. The piezoelectric vibrator according to claim 13, wherein the lid member includes:
a ceiling part opposed to the base member with the piezoelectric vibration element interposed between the base member and the ceiling part;
a side wall part extending from an outer edge portion of the ceiling part toward the base member; and
a flange part extending from an end portion of the side wall part on a side thereof closer to the base member to a side opposite to the internal space.

15. The piezoelectric vibrator according to claim 1, wherein the lid member comprises a ceramic.

16. The piezoelectric vibrator according to claim 1, wherein the base member includes:
an insulating base body in a plate shape;
a connection electrode on a first side of the base body closer to the piezoelectric vibration element and electrically connected to the piezoelectric vibration element;
an outer electrode on a second side of the base body opposite to the piezoelectric vibration element; and
a through electrode penetrating the base body an electrically connecting the connection electrode and the outer electrode.

17. The piezoelectric vibrator according to claim 1, wherein the piezoelectric vibration element is a crystal vibration element.

18. The piezoelectric vibrator according to claim 17, wherein the crystal vibration element includes an AT-cut crystal piece, and a main vibration of the crystal vibration element is a thickness shear vibration mode.

19. The piezoelectric vibrator according to claim 1, wherein the lid member includes a ceiling part opposed to the base member and a side wall part extending from the ceiling part toward the base member, the bonding part further comprises an insulating film covering an end portion of the side wall part on a side closer to the base member, and the organic adhesive bonds the insulating film to the base member.

20. The piezoelectric vibrator according to claim 19, wherein a tip portion of the insulating film has greater flatness than the end portion of the side wall part.
